(19) United States
(12) Patent Application Publication
(10) Pub. No.: US 2026/0288014 A1
(43) Pub. Date: Sep. 24, 2026

(54) METHOD OF PERFORMING A QUALIFICATION ACTION ON AN EXPOSURE APPARATUS

(71) Applicant: ASML Netherlands B.V., Veldhoven (NL)

(72) Inventors: Josephus Peter VAN LIESHOUT, Eindhoven (NL); Aleksei Levan NAZARIAN, Eindhoven (NL); Birgitt Noelle Cornelia Liduine HEPP, Waalre (NL); Izak DE HEER, Tholen (NL)

(73) Assignee: ASML Netherlands B.V., Veldhoven (NL)

(21) Appl. No.: 19/475,720

(22) PCT Filed: Apr. 9, 2024
(86) PCT No.: PCT/EP2024/059585

§ 371 Date: Oct. 15, 2025

(30) Foreign Application Priority Data
May 9, 2023 (EP) 23172341.2

(51) Int. Cl. G03F 7/00; G05B 15/02; H10P 72/50

(52) U.S. Cl. CPC G03F 7/70508; G03F 7/706837; G05B 15/02; H10P 72/57

(57) ABSTRACT

Disclosed is a method of performing a system qualification action relating to an exposure apparatus or a component thereof. The method comprises obtaining test timing data and reference timing test data relating to one or more test timing parameters, each test timing parameter describing a respective system action duration, where each system action duration describes a duration of a respective system action of said exposure apparatus or component thereof, and qualifying said exposure apparatus or component thereof in terms of one or more quality performance parameters based on a comparison of said test timing data and said reference timing test data.

### CROSS-REFERENCE TO RELATED APPLICATIONS

This application claims priority of EP application 23172341.2 which was filed on May 9, 2023 and which is incorporated herein in its entirety by reference.

### FIELD OF THE INVENTION

The present invention relates to methods and apparatus usable, for example, in the manufacture of devices by lithographic techniques, and to methods of manufacturing devices using lithographic techniques.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

It is necessary to routinely qualify or assess performance of a tool, either when a tool is first installed or delivered, or when it is serviced (e.g., undergoes a maintenance action such as replacement of a component or any hardware or software update). The performance is typically measured in terms of five key performance metrics: focus, imaging, defectivity, overlay and productivity. To properly qualify the tool in terms of all of these performance metrics takes considerable time.

It is desirable to reduce the time presently spent on such qualification actions.

### SUMMARY OF THE INVENTION

The invention in a first aspect provides a method of performing a system qualification action relating to an exposure apparatus or a component thereof, the method comprising: obtaining test timing data relating to one or more test timing parameters, each test timing parameter describing a respective system action duration, where each system action duration describes a duration of a respective system action of said exposure apparatus or component thereof; obtaining reference timing test data comprising reference values for said one or more system action durations; and qualifying said exposure apparatus or component thereof in terms of one or more quality performance parameters based on a comparison of said test timing data and said reference timing test data.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus; and

FIG. 2 illustrates schematically measurement and exposure processes in the apparatus of FIG. 1.

### DETAILED DESCRIPTION OF EMBODIMENTS

Before describing embodiments of the invention in detail, it is instructive to present an example environment in which embodiments of the present invention may be implemented.

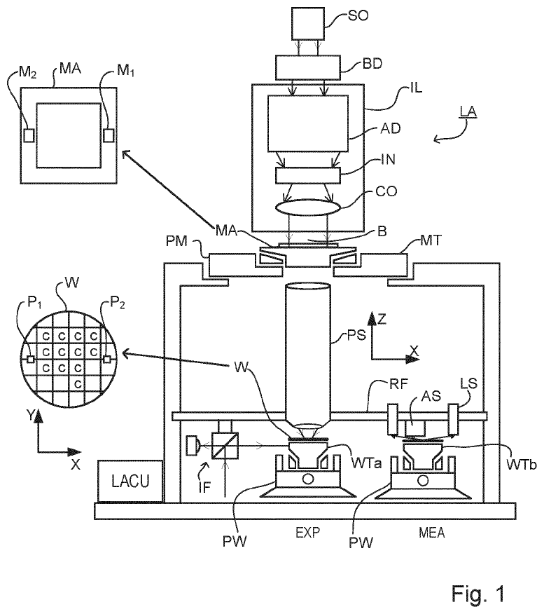

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

The lithographic apparatus may comprise an aberration sensor for the verification of an aberration fingerprint of the projection system PS. In an embodiment such an aberration fingerprint, i.e. aberrations per field point of the projection system PS, may be determined using a such wavefront aberration sensor. A wavefront aberration sensor of a known type, for instance such as described in US2002/0001088 may be used. Such a wavefront aberration sensor may be based on the principle of shearing interferometry and comprises a source module and a sensor module. The source module may comprise a patterned layer of chromium that is placed in the object plane (i.e. where during production the pattern of the patterning means is) of the projection system PS and has additional optics provided above the chromium layer. The combination provides a wavefront of radiation to the entire pupil of the projection system PS. The sensor module may comprise a patterned layer of chromium that is placed in the image plane of the projection system (i.e. where during production the substrate W is) and a camera that is placed some distance behind said layer of chromium. The patterned layer of chromium on the sensor module diffracts radiation into several diffraction orders that interfere with each other giving rise to an interferogram. The interferogram is measured by the camera. The aberrations in the projection lens can be determined by software based upon the measured interferogram. The wavefront aberration sensor may be configured to transfer information with respect to the aberration fingerprint towards the control unit.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations-an exposure station EXP and a measurement station MEA-between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

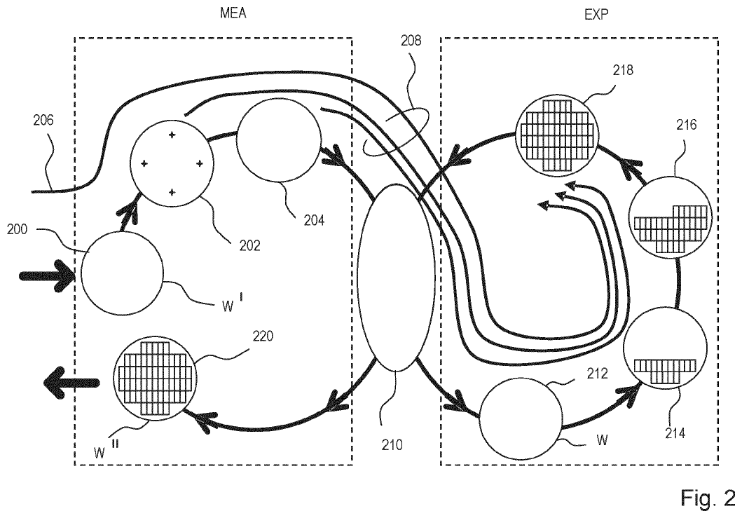

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W′ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

There are many actions and events which may typically prompt the performance of an exposure apparatus qualification action. For example, such a qualification may be performed prior to or as part of installing an exposure apparatus at a site or fabrication plant and/or subsequently to performance of a maintenance action. Such a maintenance action may comprise, for example, replacement of a hardware component which is subject to degradation over time (e.g., replacement of a wafer table or projection lens) or replacement or update of a software module. Exposure apparatus qualification may also be performed when developing new products (e.g., hardware and/or software modules).

At a system level, such a qualification action may measure the final performance of the exposure apparatus in terms of system-level performance parameters. These system-level performance parameters may comprise productivity performance (e.g., relating to productivity or speed) and a number of quality performance parameters, namely: focus performance, imaging performance, defectivity performance and overlay performance. In addition, many more Critical to Quality (CtQ) parameters may be measured at module level.

In the context of this disclosure, the qualification may comprise a qualification of any exposure apparatus or any module or component thereof. An exposure apparatus may comprise any one or more of a lithographic apparatus (e.g., which prints via exposure) or a lithographic apparatus such as a scatterometer or a scanning electron microscope/e-beam apparatus (e.g., which measures via exposure).

Presently, many different tests are executed to measure all these individual parameters, which leads to high consumption of time and resources. For example, to qualify focus performance, it is known to use an alignment sensor to measure the focus setting used to expose a special type of focus sensitive alignment mark or focus mark. Many of these marks may be exposed and read in a focus testing procedure. Such procedures take a few to several hours, during which time the tool is offline. Similar or longer timescales may be attributable to the other qualification tests for the other system-level performance parameters.

It is desirable therefore, to reduce the time spent on qualification. For example, it is known to use Fast Ship strategies for system installation, in which some of these qualification steps are skipped. This results in a time gain at the cost of an increased risk of missing performance issues. As such, it would be desirable to develop new qualification methods, which are of short duration but do not result in an unacceptable loss of quality.

One qualification test typically performed, whether in new product integration, software service pack qualification or factory output, is a productivity qualification test, also referred to as an endurance productivity test or endurance ATP productivity test. This test is particularly desirable as productivity performance is a particularly important performance metric. Additionally, the productivity qualification test is a relatively cheap test to execute, typically consuming only 20-35 minutes of machine time.

The productivity qualification test may comprise performing (e.g., dummy) exposures on a plurality of wafers. The exposures may be performed using a plurality (e.g., two) different reticles, each with a respective different pattern. The exposures may be dummy exposures, insofar as the wafer is not coated with resist; all else should be essentially the same as a real exposure. The exposures may be performed over multiple lots of wafers, each lot relating to a plurality of wafers (e.g., which may range between 5 and 15 wafers per lot and may vary in number from lot-to-lot within a test). Because the exposures may be dummy exposures, it may be that only a few physical wafers are actually used (e.g., fewer than 20, fewer than 10 or fewer than 5 wafers; 4 wafers is typical), with each wafer exposed multiple times during the test to mimic the exposure of the multiple lots of wafers (e.g., more than 40 more than 50 or more than 60 wafers). The different lots may relate to different settings, different reticles (or may even include a reticle swap mid-lot) and/or different numbers of (e.g., reused) wafers.

The main purpose of a productivity qualification test is to derive the performance with respect to productivity specifications. In particular, the productivity qualification test may measure and qualify productivity (e.g., speed) in terms of wafer throughput (e.g., in terms of wafers/hour). Additionally this test may also separately quantify other productivity metrics such as determining the time overhead incurred for one or both of reticle exchanges and/or lot changes.

However, it can be appreciated that during productivity qualification test, a large number of lower level timings and durations (test time data) relating to various actions are recorded during system operation. It is therefore proposed to perform a system qualification action relating to a exposure apparatus, apparatus or a component thereof, in terms of qualifying one or more (system-level) quality performance parameters (e.g., one or more of focus, imaging, defectivity, overlay), based on test timing data describing one or more system action durations, where each system action duration describing a duration of a respective system action. Such test timing data may be the timing data typically obtained as a result of performing a productivity qualification test, and may comprise (purely for example) the time taken to perform system actions such as inter alia: wafer clamping, exposure scan, preparatory move, reticle align, lens correction adjustment, wafer transfer (e.g., between a wafer handler to wafer table) and/or any moving of any system component of the exposure apparatus. It may be appreciated that several of the CtQ parameters which impact the other four system-level performance parameters (focus, imaging, defectivity and overlay) have a timing component associated with them.

As such, the inventors recognize that many performance issues can be determined by analyzing these lower level timings or test timing data, and therefore conclusions on how the tool is performing may be drawn and/or predictions on potential quality issues made based on this test timing data.

An advantage of using these lower level timings is that, in general, there is a predictable/logical relation between these timings and one or more of the performance parameters of interest (quality performance parameters. Additionally, the individual timing measurements comprised within the test timing data are typically less prone to variation (e.g., noise) than the (generally more stochastic) performance metrics such as overlay or number of defects/wafer.

By way of a first specific example, (e.g., immersion) defectivity performance can be shown to be strongly dependent on exposure meander routing. This exposure meander routing, in turn, can be broken down into the two per-field durations within the test timing data: exposure scan duration and preparatory move duration. Any changes in these durations (e.g., statistically significant or over that expected from wafer-to-wafer variation) is indicative of a slightly changed routing, which poses a defectivity risk. As such, by monitoring these durations, which are typically recorded during a productivity qualification test, a defectivity assessment or prediction may be made. Therefore these two per-field durations may be used for defectivity performance parameter qualification.

For example, consider a situation where a software update introduces a bug in the routing software. This bug causes a cornered move during exposure of one or more (e.g., edge) fields, rather than the desired diagonal move. These different moves are reflected in the exposure scan duration and preparatory move duration timing. Therefore, by measuring the timing difference, an anomaly may be detected and a respective defectivity performance issue flagged. In turn this should enable detection of this bug, e.g., it may trigger further analysis to properly identify the unintended routing changes.

In another specific example, the duration of wafer clamping and/or wafer conditioning steps, e.g., either within the wafer handling module on the wafer table, are known to have potential impact on overlay. Changes in these timings may indicate changes in the thermal condition of the wafer as the wafer may be conditioned within the wafer handling module (e.g., to a desired temperature) and longer times to do this may be indicative of thermal issues. Such thermal issues may be correlated with overlay performance. In particular, the time duration between wafer transfer into wafer handling module and wafer clamping onto the wafer table may be used for such overlay performance qualification.

Another timing parameter monitored during a productivity qualification test and which may be used for non-productivity qualification, is the time to perform lens adjustment in response to a lens aberration measurement (e.g., using a lens aberration sensor or wavefront sensor). An adjustment duration which is longer (or more generally different) than expected can be indicative of greater or unexpected lens aberration. This can be a predictor or qualifier for any one or more of the quality performance parameters, e.g., focus, imaging, defectivity, overlay.

Another example may be reticle alignment timing (e.g., time taken to perform a reticle align or any related duration(s)). During reticle align, the wafer stage is typically positioned for some time with one of its sensors inside the immersion fluid underneath the lens. This results in a changed thermal condition of the sensor, which as a result may deform. A measurement error between wafers may result when this conditioning period, and therefore the sensor deformation, varies from wafer to wafer.

Additionally, where the lithographic tool is an immersion tool, any sensor component subject to heating may be brought into the vicinity of the immersion chamber for longer periods than is desirable thereby affecting its thermal conditioning. Therefore any time parameter relating to the length of time in moving and/or aligning such a component may be used for qualification according to the teachings herein.

These examples are only a few of many, as it can be appreciated that there are scores of timing parameters monitored during a productivity qualification test, and many or all of these can be directly linked or correlated with one or more of the system-level quality performance parameters of interest (e.g., those other than productivity and/or in addition to productivity). In this way, an (at least partial) system qualification can be performed without executing the other qualification tests typically used to directly qualify quality performance parameters such as one or more of focus, imaging, defectivity and/or overlay.

In each case, the test timing data analysis may comprise determining timing deviations which are statistically significant, rather than simply resulting from normal wafer-to-wafer variation. The analysis may be performed per field, as it can be appreciated that timing parameters may vary from field-to-field on a wafer due to field-position, field sequencing etc., but should not vary significantly per-field wafer-to-wafer.

Such a method may comprise determining representative per-field (e.g., averaged per field over all wafers used in the test or a subset thereof) test timing data. This may be done separately for each test timing being considered. This representative test timing data can then be compared to reference test timing data to obtain comparison test timing data. For example, this step may comprise determining the comparison test timing data as post-pre test timing data comprising the difference between the representative test timing data (post data, e.g., after a software update, component swap, upgrade or other maintenance action prompting the qualification) and the reference test timing data (pre data, e.g., before the software update, component swap, upgrade or other maintenance action). The reference data may also come from one or more other (similar) machines; e.g., if the qualification is a new machine installation, then the reference data may be obtained from a previously installed similar machine. The wafer-to-wafer variation observed in the representative test timing data and reference test timing data can be determined according to any suitable statistical measure; e.g., anything within 30 (three standard deviations) may be considered to be “normal” wafer-to-wafer variation thereby defining a confidence interval. Any deviation outside of this confidence interval in the confidence test timing data may be flagged as a potential issue for one or more relevant system-level performance parameters of interest. Of course, this is only an example and any other suitable method for determining statistical significance may be used.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

The breadth and scope of the present invention should not be limited by any of the above-described exemplary embodiments, but should be defined only in accordance with the following claims and their equivalents.

1-20. (canceled)

21. A method of performing a system qualification action relating to an exposure apparatus or a component thereof, the method comprising:
obtaining test timing data relating to one or more test timing parameters, each test timing parameter describing a respective system action duration, wherein each system action duration describes a duration of a respective system action of the exposure apparatus or component thereof;
obtaining reference timing test data comprising reference values for the one or more system action durations; and
qualifying the exposure apparatus or component thereof in terms of one or more quality performance parameters based on a comparison of the test timing data and the reference timing test data.

22. The method of claim 21, wherein the test timing data comprises timing data obtained as a result of performing a productivity qualification test.

23. The method of claim 22, further comprising an initial performing the productivity qualification test to obtain the test timing data.

24. The method of claim 21, wherein the quality performance parameters comprise one or more of a focus performance parameter, an imaging performance parameter, a defectivity performance parameter and/or an overlay performance parameter.

25. The method of claim 21, wherein the timing test data comprises one or more of: wafer clamping duration data, exposure scan duration data, preparatory move duration data, reticle align duration data, lens correction adjustment duration data, wafer transfer duration data, and/or any duration relating to a movement of a system component of the exposure apparatus.

26. The method of claim 21, wherein the qualifying comprises:
determining whether the timing test data deviates from the reference timing test data; and
flagging a potential issue in terms of the one or more quality performance parameters if the timing test data deviates from the reference timing test data.

27. The method of claim 26, wherein the determining whether the timing test data deviates from the reference timing test data comprises determining whether the timing test data statistically significantly deviates from the reference timing test data.

28. The method as of claim 27, further comprising:
determining a confidence interval describing normal per-substrate variation for the test timing data; and
determining a statistically significantly deviation as one which deviates outside of the confidence interval.

29. The method of claim 21, wherein the qualifying is separately performed for each of the one or more test timing parameters within the test timing data.

30. The method of claim 21, wherein the test timing data comprises representative test timing data describing averaged test timing data over a plurality of substrates.

31. The method of claim 21, wherein the test timing data comprises per-field test timing data and the comparison of the test timing data and the reference timing test data is performed per field.

32. The method of claim 21, wherein:
the test timing data comprises test timing data relating to the exposure apparatus or component thereof subsequent to a maintenance action, and
the reference timing test data comprises test timing data relating to the exposure apparatus or component thereof prior to the maintenance action.

33. The method of claim 21, wherein the reference timing test data comprises timing test data relating to at least one different exposure apparatus or component thereof than the exposure apparatus or component thereof used to obtain the timing test data.

34. A computer program comprising program instructions operable to perform the method of claim 21, when run on a suitable apparatus.

35. A non-transient computer program carrier comprising the computer program of claim 34.

36. A processing arrangement comprising:
a non-transient computer program carrier comprising a computer program comprising program instructions operable to perform the method claim 21, when run on a suitable apparatus; and
a processor operable to run the computer program comprised on the non-transient computer program carrier.

37. An exposure apparatus comprising the processing arrangement of claim 36.

38. The exposure apparatus of claim 37, further comprising:
a lithographic apparatus.

39. The exposure apparatus of claim 37, further comprising:
a metrology apparatus.

40. A semiconductor device manufactured using the exposure apparatus of claim 37.
